(19) United States
(12) Patent Application Publication
(10) Pub. No.: US 2023/0402544 A1
(43) Pub. Date: Dec. 14, 2023

(54) FIN FIELD EFFECT TRANSISTOR AND MANUFACTURING METHOD THEREOF

(71) Applicant: Taiwan Semiconductor Manufacturing Company, Ltd., Hsinchu (TW)

(72) Inventors: Ya-Yi Tsai, Hsinchu City (TW); Sheng-Yi Hsiao, Hsinchu (TW); Chao-Hsuan Chen, Hsin-Chu (TW); Yun-Ting Chiang, Hsinchu Country (TW); Shu-Yuan Ku, Hsinchu Country (TW)

(73) Assignee: Taiwan Semiconductor Manufacturing Company, Ltd., Hsinchu (TW)

(21) Appl. No.: 17/838,303

(22) Filed: Jun. 13, 2022

(51) Int. Cl. H01L 29/78; H01L 29/66; H01L 21/762

(52) U.S. Cl. CPC H01L 29/785; H01L 29/66795; H01L 21/76224

(57) ABSTRACT

A FinFET includes a semiconductor substrate, a semiconductor fin, a gate structure, and an isolation structure. The semiconductor fin protrudes from the semiconductor substrate. The gate structure is disposed across a first segment of the semiconductor fin. The isolation structure interrupts a continuity of a second segment of the semiconductor fin. The isolation structure has a first portion and a second portion stacked on the first portion. Sidewalls of the first portion are inclined and sidewalls of the second portion are straight. A top surface of the first portion is coplanar with a top surface of the gate structure.

### BACKGROUND

As the semiconductor devices keep scaling down in size, three-dimensional multi-gate structures, such as the fin field effect transistor (FinFET), have been developed to replace planar CMOS devices. A characteristic of the FinFET device lies in that the structure has one or more silicon-based fins that are wrapped around by the gate to define the channel of the device. The gate wrapping structure further provides better electrical control over the channel.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1J are simplified top views illustrating various stages of a method of manufacturing a FinFET in accordance with some embodiments of the disclosure.

FIG. 2A to FIG. 2J are cross-sectional views illustrating various stages of the method of manufacturing the FinFET in FIG. 1A to FIG. 1J.

FIG. 3A to FIG. 3J are cross-sectional views illustrating various stages of the method of manufacturing the FinFET in FIG. 1A to FIG. 1J.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

The embodiments of the present disclosure describe the exemplary manufacturing process of FinFETs and the FinFETs fabricated there-from. The FinFET may be formed on bulk silicon substrates in certain embodiments of the present disclosure. Still, the FinFET may be formed on a silicon-on-insulator (SOI) substrate or a germanium-on-insulator (GOI) substrate as alternatives. Also, in accordance with the embodiments, the silicon substrate may include other conductive layers or other semiconductor elements, such as transistors, diodes or the like. The embodiments are not limited in this context.

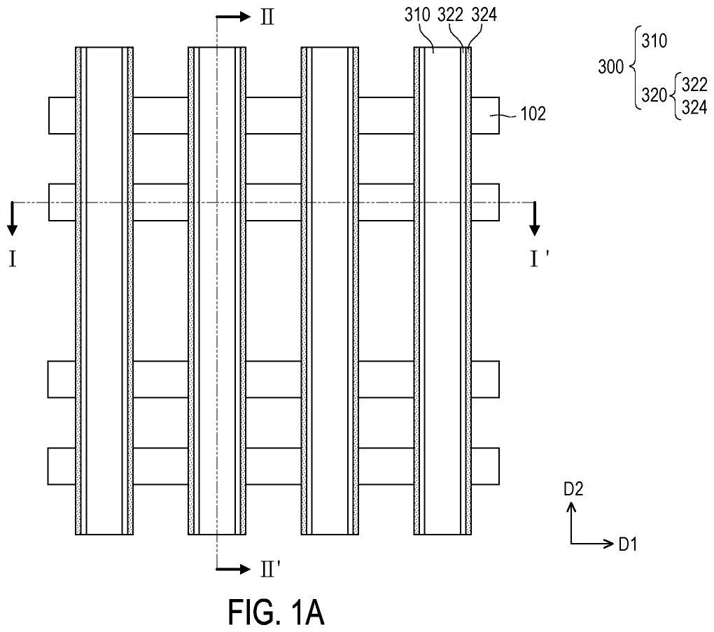

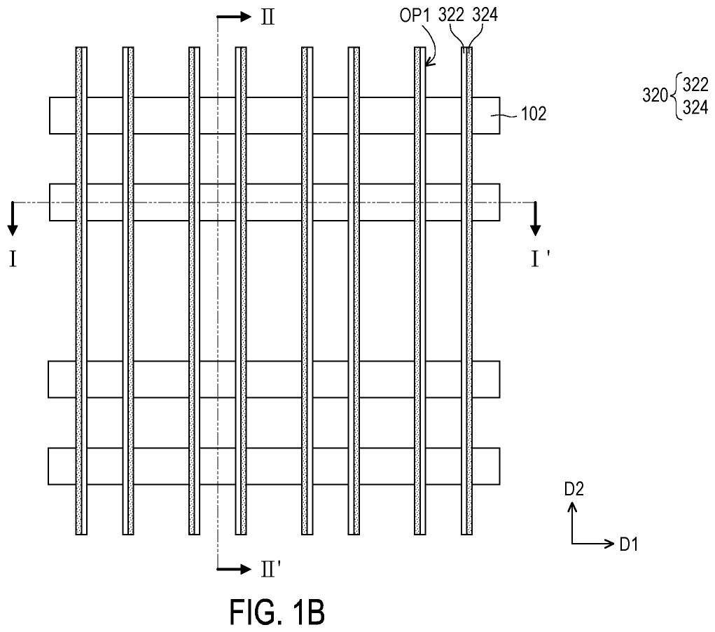

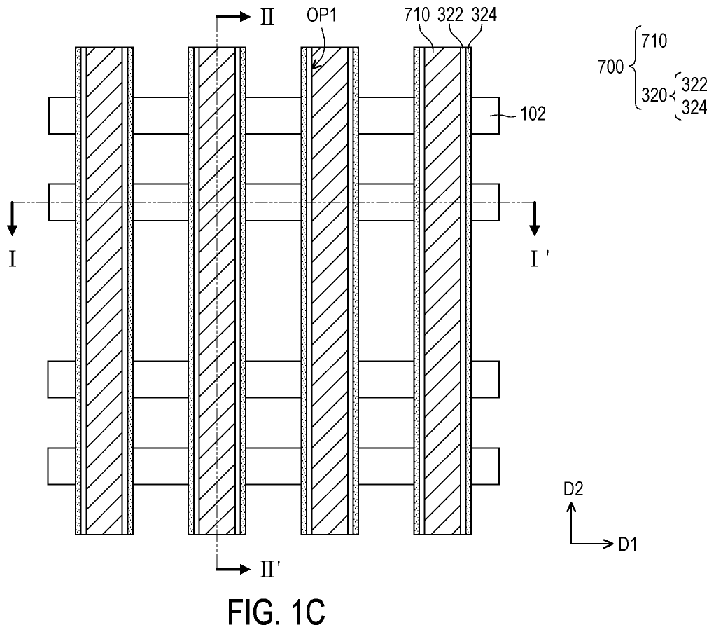

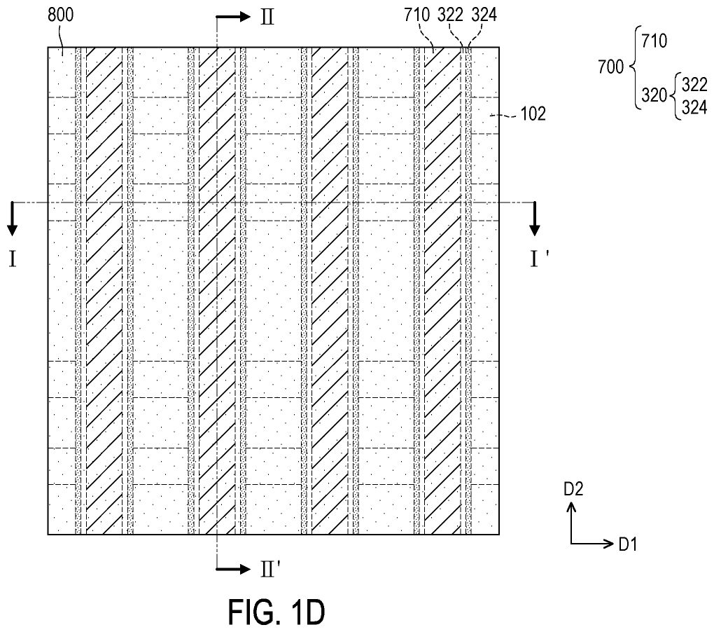

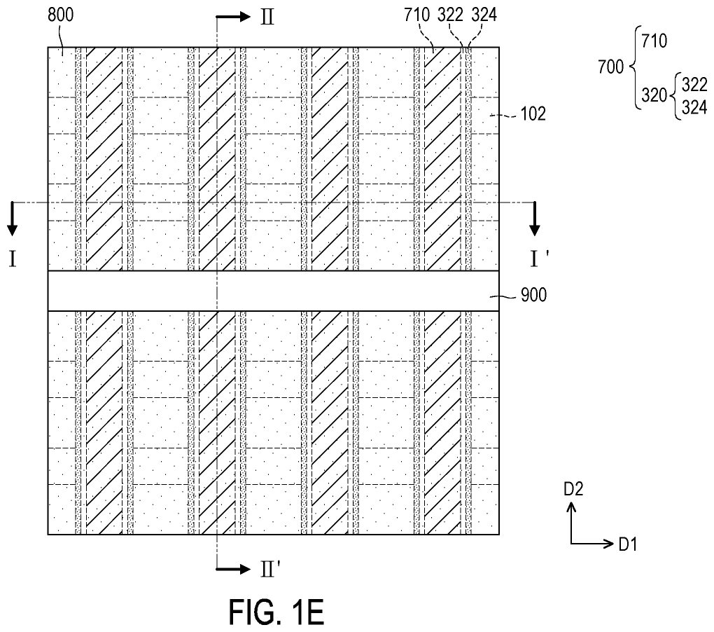

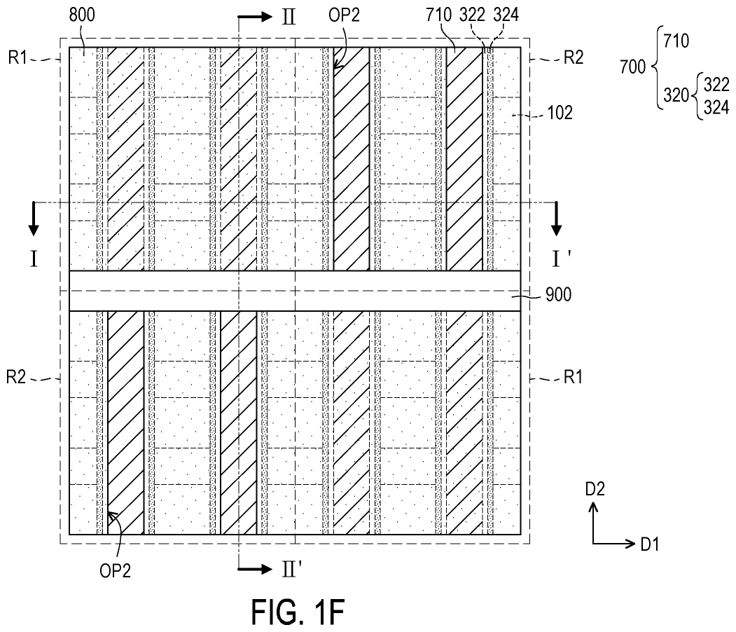

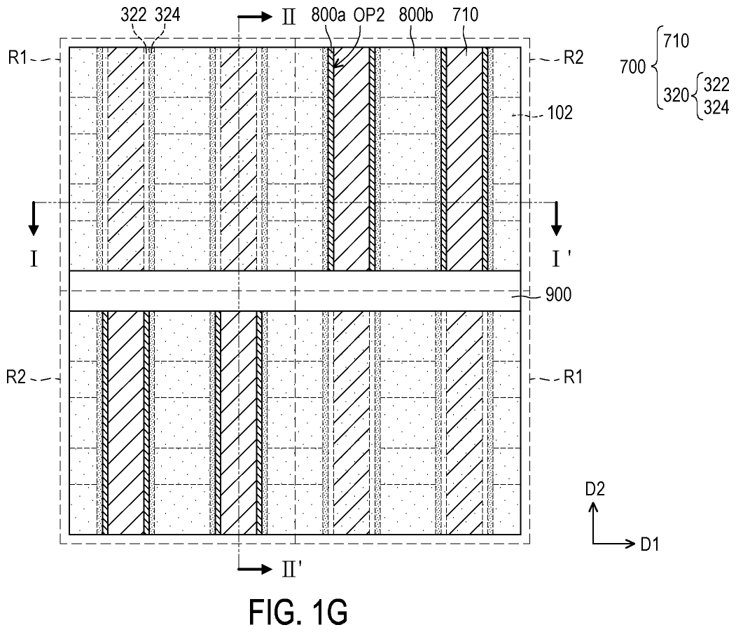

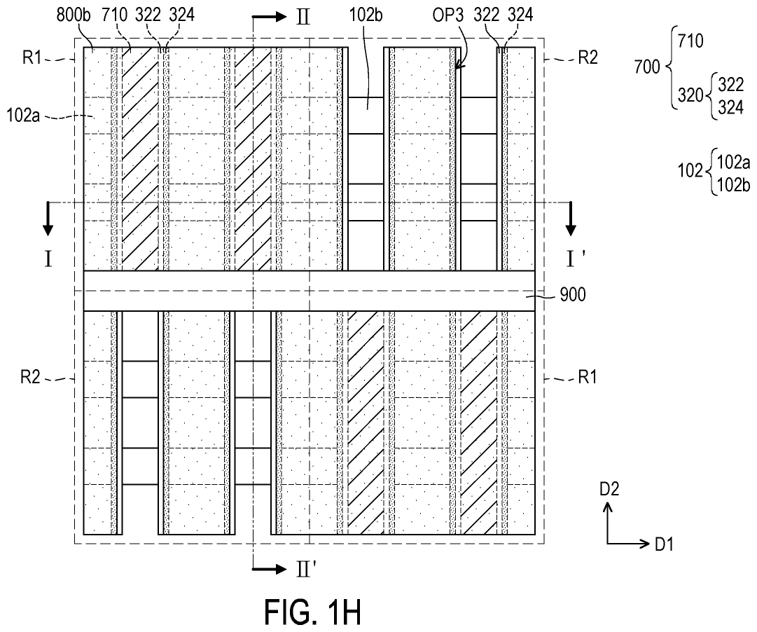

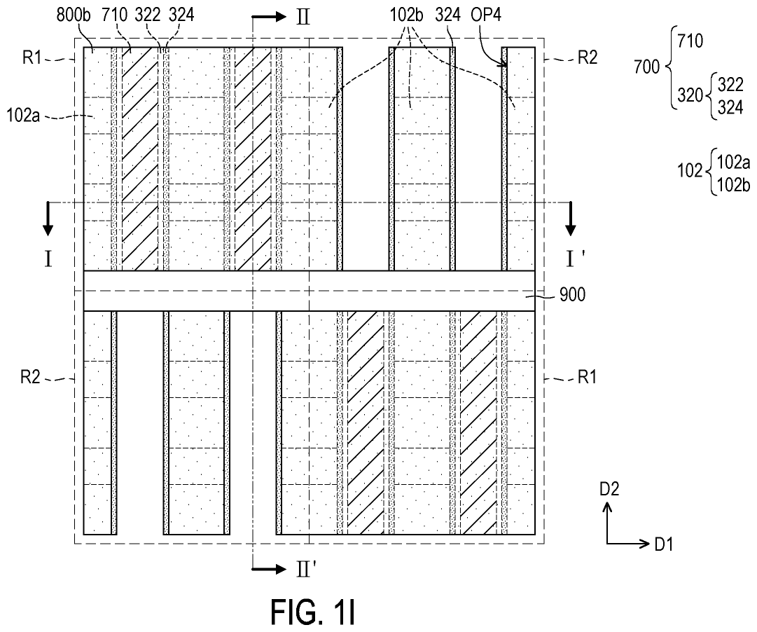

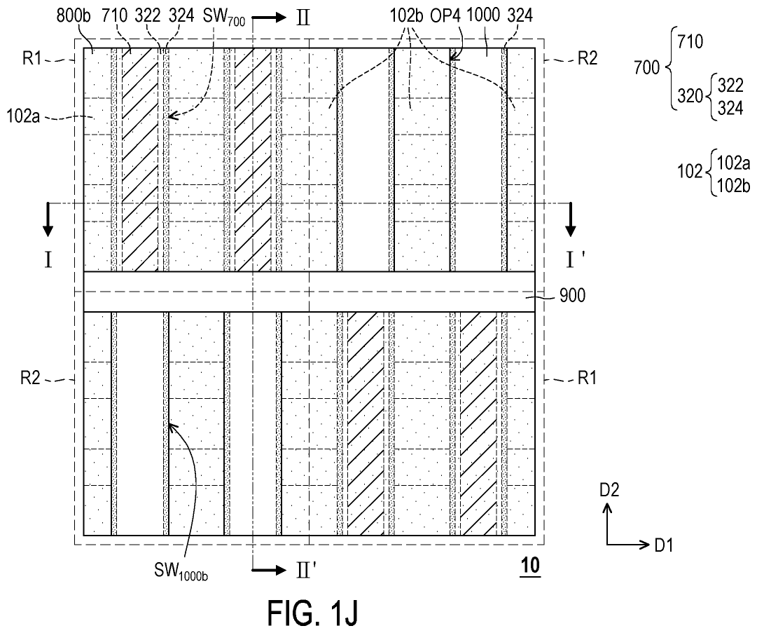

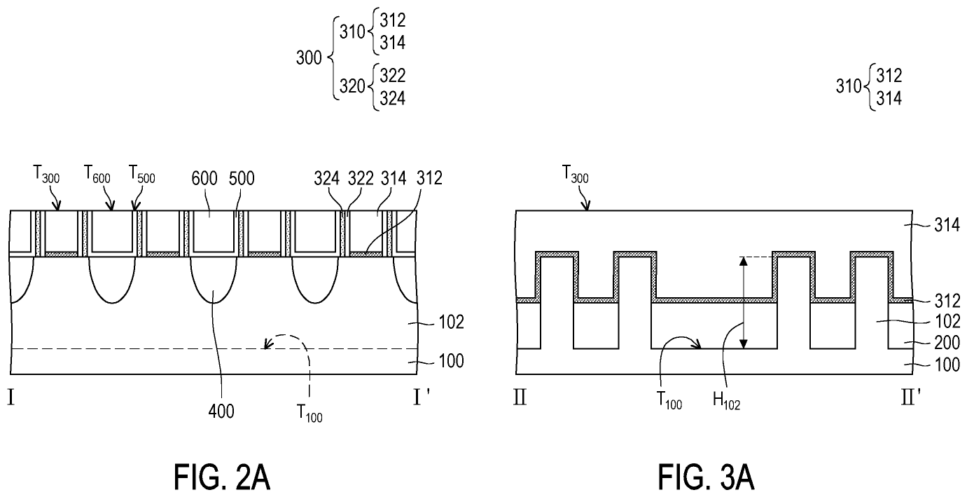

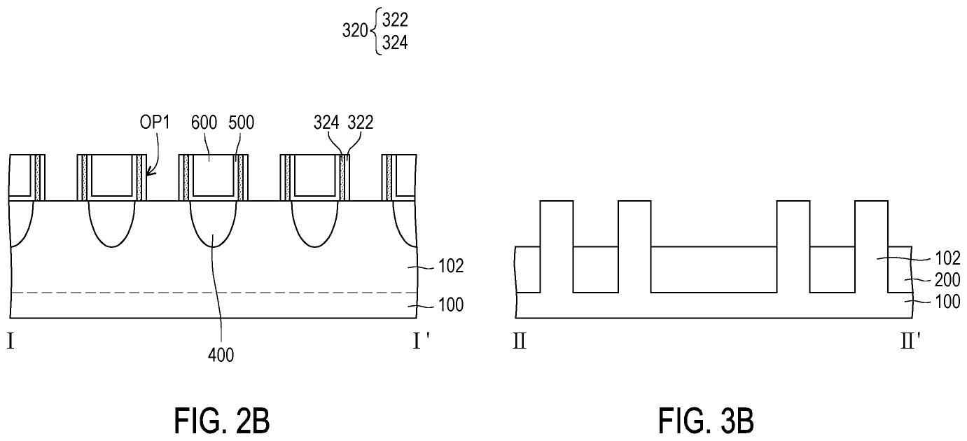

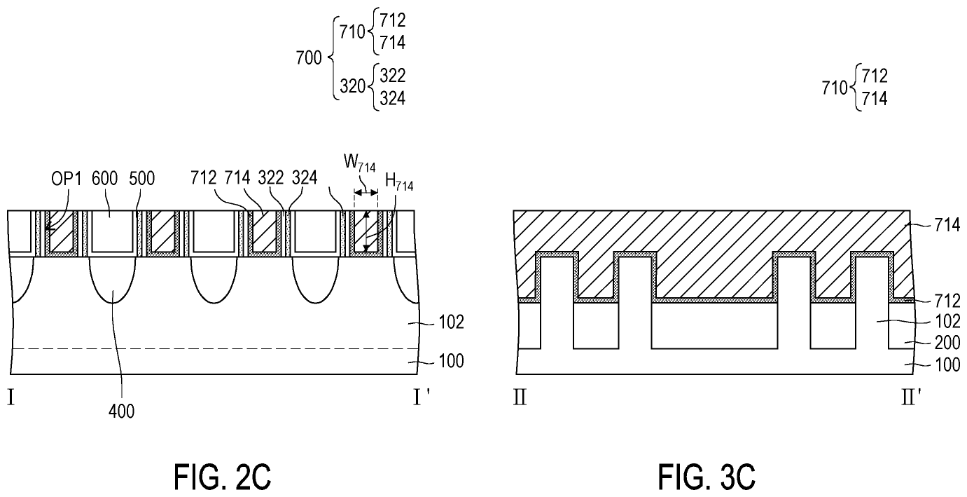

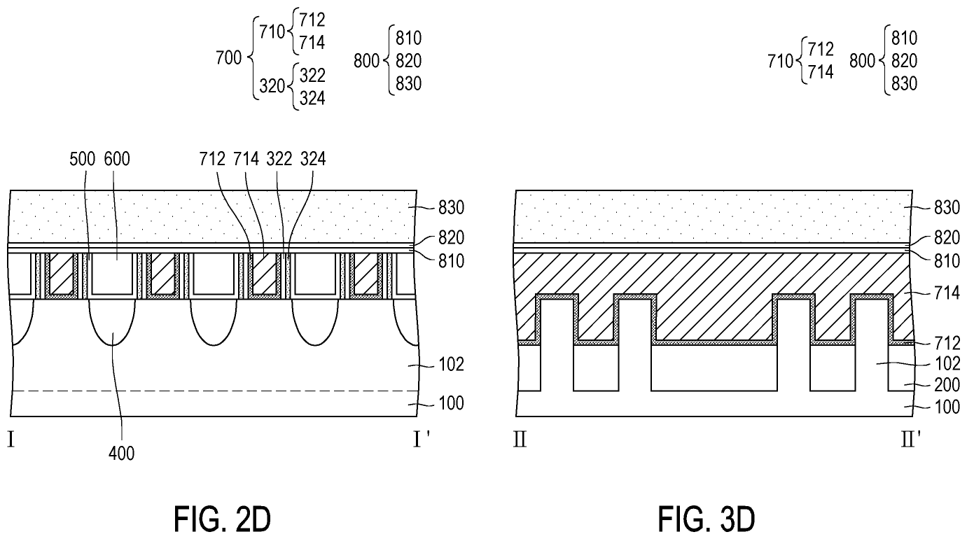

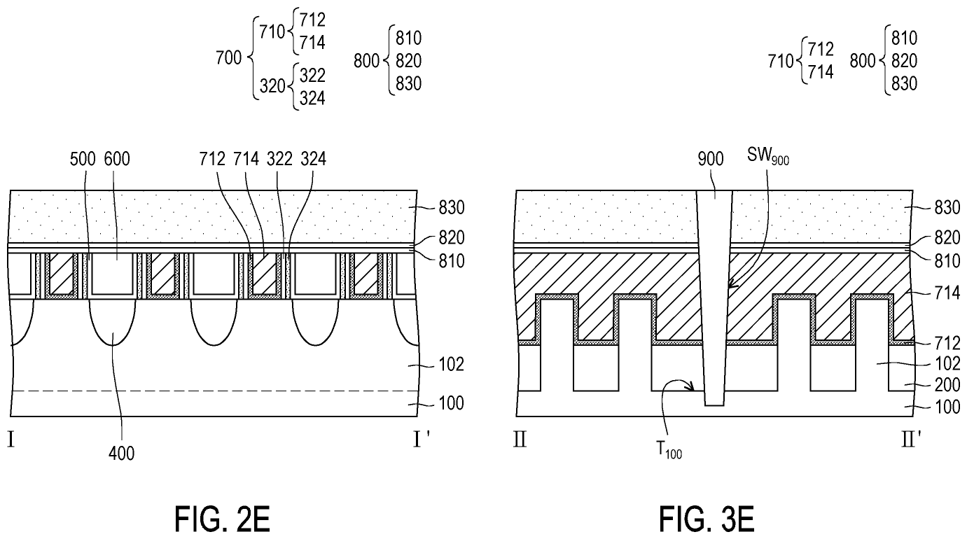

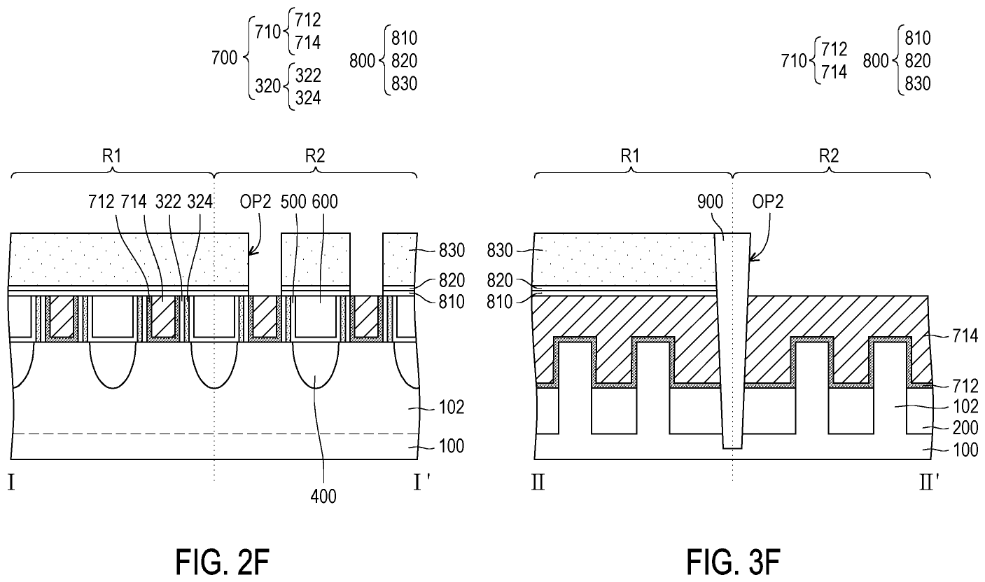

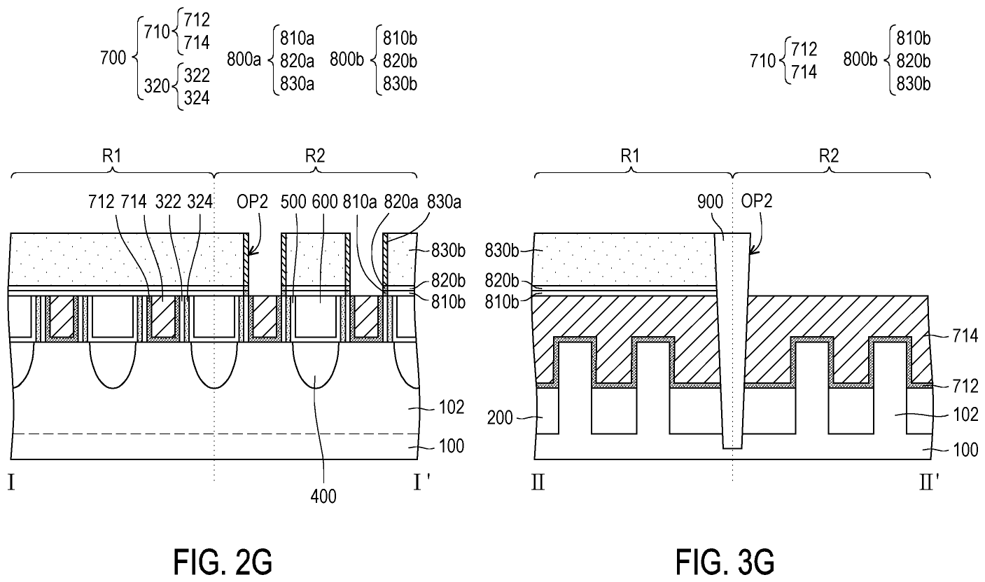

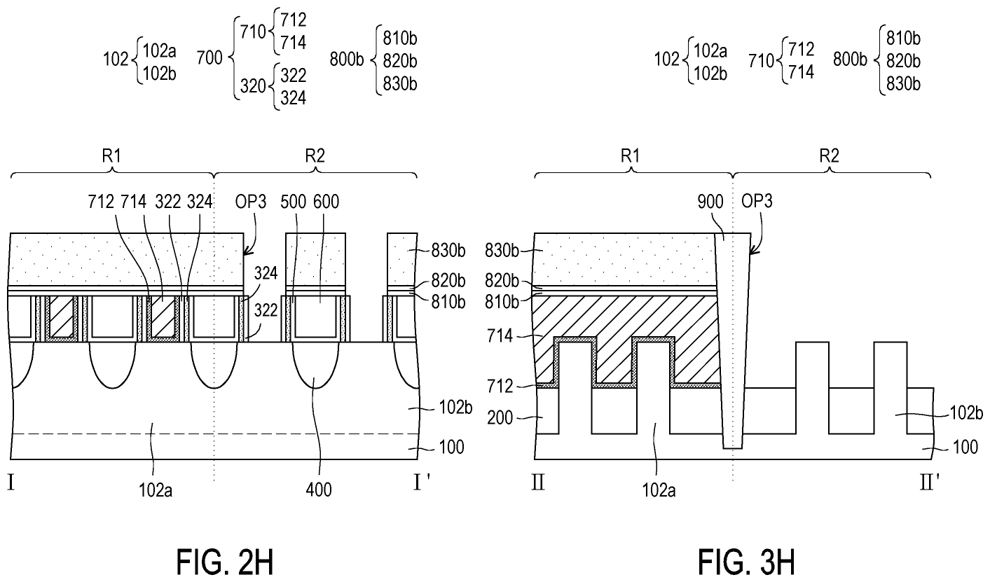

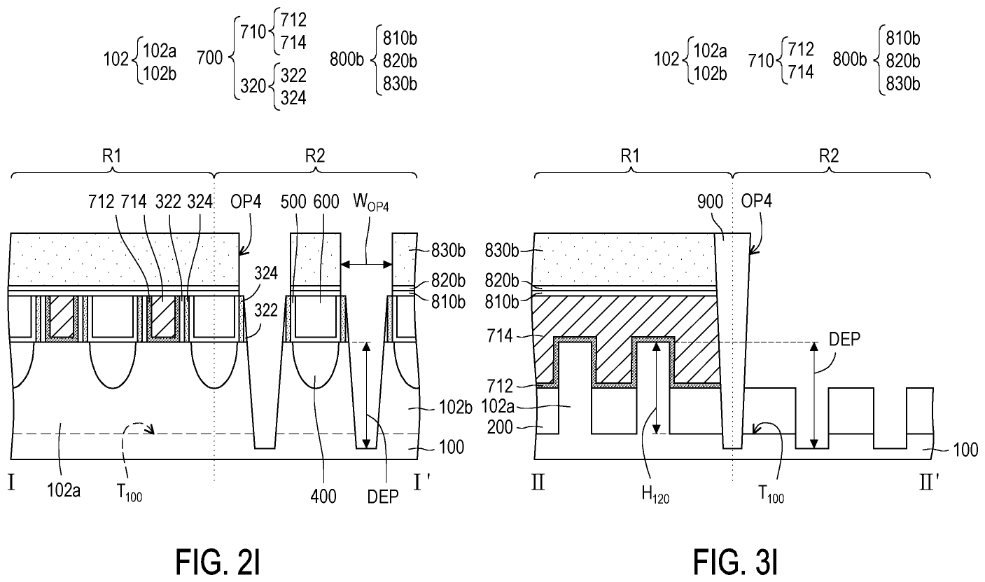

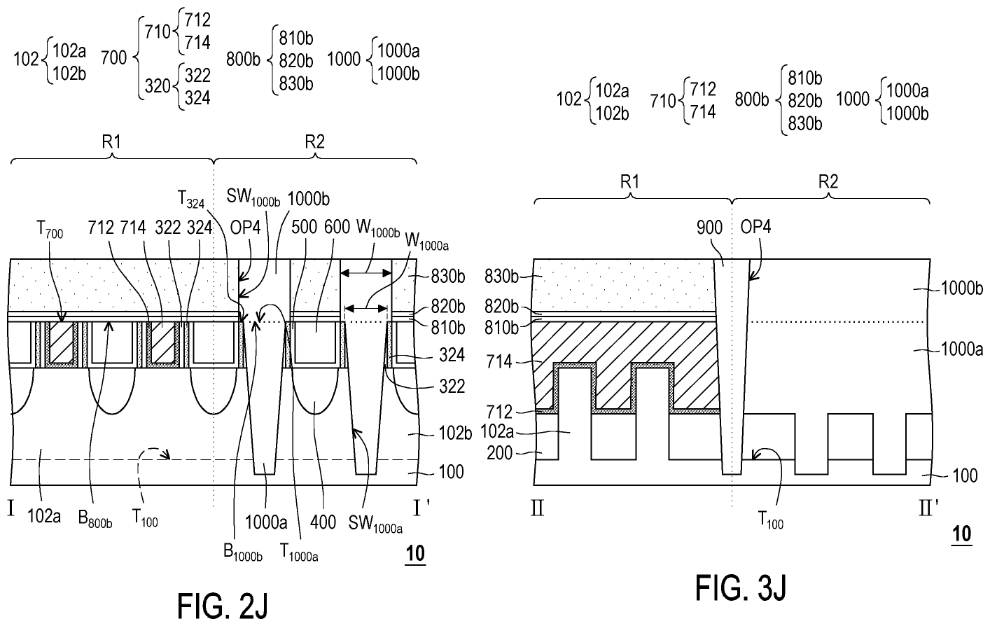

FIG. 1A to FIG. 1J are simplified top views illustrating various stages of a method of manufacturing a FinFET 10 in accordance with some embodiments of the disclosure. FIG. 2A to FIG. 2J are cross-sectional views illustrating various stages of the method of manufacturing the FinFET 10 in FIG. 1A to FIG. 1J. FIG. 3A to FIG. 3J are cross-sectional views illustrating various stages of the method of manufacturing the FinFET 10 in FIG. 1A to FIG. 1J. FIG. 2A to FIG. 2J are respectively cross-sectional views of the FinFET 10 take along the line I-I′ in FIG. 1A to FIG. 1J, and FIG. 3A to FIG. 3J are respectively cross-sectional views of the FinFET 10 taken along the line II-II′ in FIG. 1A to FIG. 1J. For simplicity and clarity, some elements shown in the cross-sectional views of FIG. 2A to FIG. 2J and FIG. 3A to FIG. 3J are omitted in the top views of FIG. 1A to FIG. 1J.

Referring to FIG. 1A, FIG. 2A, and FIG. 3A, a semiconductor substrate 100 having a plurality of semiconductor fins 102 thereon is provided. In some embodiments, the semiconductor substrate includes a silicon substrate, a silicon-on-insulator (SOI) substrate, a silicon germanium substrate, or a substrate formed of other suitable semiconductor materials. For example, the semiconductor substrate 100 may be made of other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, the semiconductor substrate 100 includes various doped regions depending on design requirements (e.g., p-type semiconductor substrate or n-type semiconductor substrate). In some embodiments, the doped regions are doped with p-type or n-type dopants. For example, the doped regions may be doped with p-type dopants, such as boron or BF₂; n-type dopants, such as phosphorus or arsenic; and/or combinations thereof. The doped regions may be configured for an n-type FinFET, or alternatively configured for a p-type FinFET.

In some embodiments, the semiconductor fins 102 protrude from the semiconductor substrate 100. For example, the semiconductor fins 102 protrude from a top surface T₁₀₀ of the semiconductor substrate 100, as shown in FIG. 2A and FIG. 3A. In some embodiments, the semiconductor fins 102 are parallel to one another and extend along a first direction D1, as shown in FIG. 1A. In some embodiments, the method of forming the semiconductor substrate 100 with the semiconductor fins 102 includes patterning a bulk substrate. The bulk substrate may be patterned by any suitable method. For example, the bulk substrate may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. In some embodiments, a sacrificial layer (not shown) is formed over a bulk substrate and patterned using a photolithography process. Spacers are formed alongside the patterned sacrificial layer using a self-aligned process. The sacrificial layer is then removed, and the remaining spacers may then be used to pattern the bulk substrate to form the semiconductor fins 102. In some embodiments, the semiconductor fins 102 have substantially straight sidewalls, as shown in FIG. 3A. However, the disclosure is not limited thereto. In some alternative embodiments, the semiconductor fins 102 are formed to have inclined sidewalls. In some embodiments, a height H₁₀₂ of each semiconductor fin 102 ranges from about 5 nm to about 100 nm.

In some embodiments, the semiconductor fins 102 and the semiconductor substrate 100 are made of the same material, such as silicon. However, the disclosure is not limited thereto. In some alternative embodiments, the semiconductor fins 102 include a material different from that of the semiconductor substrate 100. For example, the semiconductor fins 102 include silicon germanium and the semiconductor substrate 100 includes silicon.

In some embodiments, a plurality of insulators 200 is formed on the semiconductor substrate 100. For example, the insulators 200 cover a lower portion of each semiconductor fin 102 and expose an upper portion of each semiconductor fin 102. In some embodiments, the insulators 200 include a dielectric material, such as silicon oxide, silicon nitride, silicon oxynitride, or the like. The method of forming the insulators 200 includes forming an insulating material layer covering the semiconductor fins 102 and removing a portion of the insulating material with chemical mechanical polishing (CMP) and/or etching back. In some embodiments, the insulators 200 are referred to as “shallow trench isolation (STI).”

In some embodiments, a plurality of dummy gate structures 300 is formed over portions of the semiconductor fins 102 and portions of the insulators 200. In some embodiments, the dummy gate structures 300 are formed across the semiconductor fins 102. For example, the dummy gate structures 300 are parallel to one another and extend along a second direction D2, as shown in FIG. 1A. In some embodiments, the second direction D2 is perpendicular to the first direction D1. In other words, the dummy gate structures 300 are perpendicular to the semiconductor fins 102 from the top view. In some embodiments, each dummy gate structure 300 includes a dummy gate stack 310 and a pair of composite spacer aside the dummy gate stack 310.

In some embodiments, each dummy gate stack 310 includes a dummy gate dielectric layer 312 and a dummy gate electrode 314 disposed on the dummy gate dielectric layer 312. As shown in FIG. 2A, the dummy gate dielectric layers 312 are formed to cover a portion of each semiconductor fin 102. In some embodiments, the dummy gate dielectric layers 312 include silicon oxide, silicon nitride, silicon oxy-nitride, or high-k dielectrics. In some embodiments, high-k dielectrics include metal oxides. It should be noted that the high-k dielectric materials are generally dielectric materials having a dielectric constant greater than 4. Examples of metal oxides used for high-k dielectrics include oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, and/or mixtures thereof. The dummy gate dielectric layers 312 may be formed using a suitable process such as atomic layer deposition (ALD), chemical vapor deposition (CVD), physical vapor deposition (PVD), thermal oxidation, UV-ozone oxidation, or combinations thereof.

In some embodiments, each of the dummy gate electrodes 314 is a single layered structure. However, the disclosure is not limited thereto. In some alternative embodiments, the dummy gate electrodes 314 may be multi-layered structure. In some embodiment, the dummy gate electrodes 314 include a silicon-containing material, such as poly-silicon, amorphous silicon or a combination thereof. The dummy gate electrodes 314 may be formed using a suitable process such as ALD, CVD, PVD, plating, or combinations thereof.

In some embodiments, each pair of composite spacers 320 covers sidewalls of the corresponding dummy gate stack 310. In some embodiments, the composite spacers 320 cover portions of the semiconductor fins 102, as shown in FIG. 1A. In some embodiments, each pair of composite spacers 320 includes a pair of first spacers 322 and a pair of second spacers 324. In some embodiments, the first spacers 322 are sandwiched between the dummy gate electrode 314 and the second spacers 324. In some embodiments, a material of the first spacers 322 and a material of the second spacers 324 are different. For example, materials of the first spacers 322 and the second spacers 324 may respectively include SiN, SiCN, SiOCN, SiOR (wherein R is an alkyl group such as CH₃, C₂H₅, or C₃H₇), SiC, SiOC, SiON, a combination thereof, or the like.

As illustrated in FIG. 2A, a plurality of strained layers 400 is formed in the semiconductor fins 102 aside the dummy gate structures 300. In some embodiments, recesses are formed in the fins 102, and the strained layers 400 are formed by selectively growing epitaxy layers from the recesses. Specifically, the strained layers 400 are formed within the recesses and extend upwardly. Although top surfaces of the strained layers 400 are illustrated as being coplanar with top surfaces of the semiconductor fins 102 in FIG. 2A, the disclosure is not limited thereto. In some alternative embodiments, the strained layers 400 may extend beyond the top surfaces of the semiconductor fins 102 to be in physical contact with sidewalls of the second spacers 324. In some embodiments, the strained layers 400 include silicon germanium (SiGe) for a p-type FinFET device. In some alternative embodiments, the strained layers 400 include silicon carbon (SiC), silicon phosphate (SiP), SiCP or a SiC/SiP multi-layer structure for an n-type FinFET device. In some embodiments, the strained layers 400 may be optionally implanted with an n-type dopant or a p-type dopant as needed. Following the formation of the strained layers 400, silicide layers may be formed by siliciding the top portions of the strained layers 400. In some embodiments, the strained layers 400 may function as source/drain regions of the subsequently formed FinFET 10.

In some embodiments, a contact etch stop layer (CESL) 500 and an interlayer dielectric layer 600 are formed aside the dummy gate structures 300. In other words, the CESL 500 and the interlayer dielectric layer 600 are formed adjacent to the composite spacers 320. In some embodiments, the CESL 500 and the interlayer dielectric layer 600 are formed on the strained layer 400, as shown in FIG. 2A. In some embodiments, the CESL 500 is formed to wrap around the interlayer dielectric layer 600. For example, the CESL 500 covers sidewalls and a bottom surface of the interlayer dielectric layer 600. In some embodiments, the CESL 500 includes SiN, SiC, or the like. On the other hand, the interlayer dielectric layer 600 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some other embodiments, the interlayer dielectric layer 600 includes low-k dielectric materials. Examples of low-k dielectric materials include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof. It is understood that the interlayer dielectric layer 600 may include one or more dielectric materials and/or one or more dielectric layers.

The method of forming the CESL 500 and the interlayer dielectric layer 600 includes depositing their respective material to cover the strained layers 400 and the dummy gate structures 300 through Flowable CVD (FCVD), CVD, HDPCVD, SACVD, spin-on, sputtering, or other suitable methods, followed by removing a portion of their respective material with CMP, etching back, and/or other suitable methods. As illustrated in FIG. 2A, top surfaces T₃₀₀ of the dummy gate structures 300, a top surface T₅₀₀ of the CESL 500, and a top surface T₆₀₀ of the interlayer dielectric layer 600 are substantially coplanar.

Referring to FIG. 1A to FIG. 1B, FIG. 2A to FIG. 2B, and FIG. 3A to FIG. 3B, a portion of each dummy gate structure 300 is removed to from a plurality of openings OP1. For example, the dummy gate stacks 310 (i.e. the dummy gate dielectric layers 312 and the dummy gate electrodes 314) are removed. In some embodiments, the dummy gate dielectric layers 312 and the dummy gate electrodes 314 are removed through an etching process or other suitable processes. For example, the dummy gate dielectric layers 312 and the dummy gate electrodes 314 may be removed through wet etching or dry etching. Example of wet etching includes chemical etching and example of dry etching includes plasma etching, but the disclosure is not limited thereto. Other commonly known etching method may also be adapted to perform the removal of the dummy gate dielectric layers 312 and the dummy gate electrodes 314. In some embodiments, the openings OP1 expose a portion of each semiconductor fin 102. In some embodiments, the portions of the semiconductor fins 102 exposed by the openings OP1 may act as channel regions for the subsequently formed FinFET 10. As illustrated in FIG. 1B, the openings OP1 extend along the second direction D2.

Referring to FIG. 1C, FIG. 2C, and FIG. 3C, a plurality of gate stacks 710 are formed into the openings OP1 such that the composite spacers 320 are disposed aside the gate stacks 710. In some embodiments, each gate stack 710 includes a gate dielectric layer 712 and a gate electrode 714. In some embodiments, the gate dielectric layers 712 are disposed on the portions of the semiconductor fins 102 that are exposed by the openings OP1. In some embodiments, the gate dielectric layers 712 further cover sidewalls of the first spacers 322. On the other hand, the gate electrodes 714 are disposed on the gate dielectric layers 712. In some embodiments, each gate dielectric layer 712 wraps around the corresponding gate electrode 714. For example, each gate dielectric layer 712 covers sidewalls and a bottom surface of the corresponding gate electrode 714. In other words, each gate dielectric layer 712 exhibits a U shape in the cross-sectional view, as shown in FIG. 2C.

In some embodiments, a material of the gate dielectric layers 712 is different from the material of the dummy gate dielectric layers 312. However, the disclosure is not limited thereto. In some alternative embodiments, the material of the gate dielectric layers 712 may be the same as the material of the dummy gate dielectric layers 312. In some embodiments, the gate dielectric layers 712 include silicon oxide, silicon nitride, silicon oxy-nitride, high-k dielectric materials, or a combination thereof. In some embodiments, high-k dielectric materials include metal oxides such as oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, and/or a combination thereof. The gate dielectric layers 712 are formed using a suitable process such as ALD, CVD, PVD, FCVD, thermal oxidation, UV-ozone oxidation, or a combination thereof. Each of the gate dielectric layers 712 may further include an interfacial layer (not shown). For example, the interfacial layer may be used in order to create a good interface between the semiconductor fins 102 and the gate electrodes 714, as well as to suppress the mobility degradation of the channel carrier of the semiconductor device. Moreover, the interfacial layer is formed by a thermal oxidation process, a CVD process, or an ALD process. A material of the interfacial layer includes a dielectric material, such as a silicon oxide layer or a silicon oxynitride layer.

In some embodiments, a material of the gate electrodes 714 includes metal, metal alloy, or metal nitride. For example, the gate electrodes 714 may include TiN, WN, TaN, Ru, Ti, Ag, Al, TiAl, TiAlN, TaC, TaCN, TaSiN, Mn, or Zr. In some embodiments, each gate electrode 714 further includes a barrier layer, a work function layer, or a combination thereof. As mentioned above, an interfacial layer may be included between the gate electrodes 714 and the semiconductor fins 102, but the disclosure is not limited thereto. In some alternative embodiments, a liner layer, a seed layer, an adhesion layer, or a combination thereof may also be included between the gate electrodes 714 and the semiconductor fins 102. In some embodiments, a height H₇₁₄ of each gate electrode 714 ranges from about 5 nm to about 200 nm. On the other hand, a width W₇₁₄ of each gate electrode 714 ranges from about 5 nm to about 100 nm.

In some embodiments, the gate stacks 710 and the composite spacers 320 are collectively referred to as gate structures 700. In other words, each gate structure 700 includes the gate dielectric layer 712, the gate electrode 714, the first spacers 322, and the second spacers 324. As illustrated in FIG. 2C, the first spacers 322 are disposed on sidewalls of the corresponding gate stack 710. That is, the first spacers 322 are sandwiched between the gate stack 710 and the second spacers 324. In some embodiments, the gate structures 700 are formed across the semiconductor fins 102. For example, the gate structures 700 are parallel to one another and extend along the second direction D2, as shown in FIG. 1C.

In some embodiments, the process shown in FIG. 1A to FIG. 1C, FIG. 2A to FIG. 2C, and FIG. 3A to FIG. 3C may be referred to as a “metal gate replacement process.” That is, the dummy gate stacks 310 including polysilicon are replaced by the gate stacks 710 which includes metal. Since the dummy gate stacks 310 are being replaced by the gate stacks 710, subsequent processes of forming metallic interconnection (not shown) can be implemented. For instance, other conductive lines (not shown) may be formed to electrically connect the gate electrode 714 with other elements.

Referring to FIG. 1D, FIG. 2D, and FIG. 3D, a hard mask layer 800 is deposited on the gate structures 300, the CESL 500, and the interlayer dielectric layer 600. In some embodiments, the hard mask layer 800 is a tri-layered structure. For example, the hard mask layer 800 includes a first sub-layer 810, a second sub-layer 820, and a third sub-layer 830. In some embodiments, the first sub-layer 810, the second sub-layer 820, and the third sub-layer 830 are stacked on the gate structures 300, the CESL 500, and the interlayer dielectric layer 600 in sequential order. In other words, the second sub-layer 820 is sandwiched between the first sub-layer 810 and the third sub-layer 830. In some embodiments, a material of the first sub-layer 810 and a material of the third sub-layer 830 are the same. Meanwhile, a material of the second sub-layer 820 is different from the material of the first sub-layer 810 and the third sub-layer 830. For example, the material of the first sub-layer 810 and the third sub-layer 830 includes silicon nitride or the like. On the other hand, the material of the second sub-layer 820 includes silicon or the like. However, the disclosure is not limited thereto. In some alternative embodiments, the material of the first sub-layer 810, the material of the second sub-layer 820, and the material of the third sub-layer 830 are all different. In some embodiments, the first sub-layer 810, the second sub-layer 820, and the third sub-layer 830 are formed by suitable deposition processes, such as CVD, PVD, ALD, or the like.

Referring to FIG. 1E, FIG. 2E, and FIG. 3E, an insulating structure 900 is formed to penetrate through the hard mask layer 800, the gate structures 700, and the insulators 200. For example, the insulating structure 900 penetrates through, from top to bottom, the third sub-layer 830, the second sub-layer 820, the first sub-layer 810, the gate electrodes 714, the gate dielectric layers 712, and the insulators 200. Meanwhile, the insulating structure 900 also penetrates through the first spacers 322 and the second spacers 324. In some embodiments, the insulating structure 900 further extends into the semiconductor substrate 100. For example, the insulating structure 900 extends below the top surface T₁₀₀ of the semiconductor substrate 100. As illustrated in FIG. 1E, the insulating structure 900 extends along the first direction D1. In other words, the insulating structure 900 is parallel to the semiconductor fins 102. For example, the insulating structure 900 is located between two adjacent semiconductor fins 102, as shown in FIG. 1E and FIG. 3E. In some embodiments, the insulating structure 900 is perpendicular to the gate structures 700 form the top view. In some embodiments, the insulating structure 900 is formed to have inclined sidewalls SW₉₀₀. For example, a width of the insulating structure 900 gradually decreases from top to bottom. As illustrated in FIG. 3E, the insulating structure 900 exhibits a trapezoidal shape from the cross-sectional view.

In some embodiments, the insulating structure 900 includes silicon oxide, silicon nitride or a suitable insulating material. In some embodiments, the insulating structure 900 is deposited through CVD, PVD, ALD, or other suitable deposition process. In some embodiments, the insulating structure 900 is made of a single material. However, the disclosure is not limited thereto. In some alternative embodiments, the insulating structure 900 includes a multi-layer structure. In some embodiments, the insulating structure 900 may be formed by removing a portion of the hard mask layer 800, a portion of the gate structures 700, a portion of the insulators 200, and a portion of the semiconductor substrate 100 through a lithography and etching process to form an opening (not shown). Thereafter, the materials listed above may be filled into the opening to form the insulating structure 900.

As illustrated in FIG. 1E and FIG. 3E, the insulating structure 900 cuts each gate structure 700. In other words, the insulating structure 900 interrupts a continuity of each gate structure 700 such that the gate structures 700 are disconnected. In some embodiments, the process illustrated in FIG. 1E, FIG. 2E, and FIG. 3E is referred to as a “cut metal gate (CMG) process” and the insulating structure 900 is referred to as a “CMG layer.”

Referring to FIG. 1F, FIG. 2F, and FIG. 3F, a plurality openings OP2 is formed in the hard mask layer 800. As illustrated in FIG. 1F, the subsequently formed FinFET 10 may be divided into a plurality of first regions R1 and a plurality of second regions R2 adjacent to the first regions R1. In some embodiments, the first regions R1 and the second regions R2 are arranged alternately. For example, the first regions R1 and the second regions R2 are arranged in a chess board manner, as shown in FIG. 1F. In some embodiments, the openings OP2 are formed in the second regions R2. For example, the openings OP2 are formed in the second region R2 to expose the gate stacks 710 located in the second regions R2. On the other hand, the gate stacks 710 located in the first regions R1 are still covered by the hard mask layer 800. Meanwhile, the composite spacers 320 are also covered by the hard mask layer 800. In some embodiments, the openings OP2 are formed by a photolithography and an etching process. For example, a photoresist layer (not shown) is formed on the hard mask layer 800. The photoresist layer has apertures that correspond to the locations of the openings OP2, and the apertures expose a portion of the hard mask layer 800. Thereafter, the portion of the hard mask layer 800 that is exposed by the photoresist layer is removed through a dry etching process to form the openings OP2 in the hard mask layer 800. In some embodiments, the etchant for this dry etching process includes gases of CF₄, CHF₃, CH₂F₂, CH₃F, CF₄, O₂, N₂, Ar, He, and/or a combination thereof. As illustrated in FIG. 1F, the openings OP2 extend along the second direction D2.

Referring to FIG. 1F to FIG. 1G, FIG. 2F to FIG. 2G, and FIG. 3F to FIG. 3G, a portion of the hard mask layer 800 that is in proximity to the openings OP2 is transformed into a plurality of sacrificial hard mask patterns 800a. On the other hand, the remaining hard mask layer 800 constitutes the hard mask layer 800b. In some embodiments, the portion of the hard mask layer 800 is transformed into the sacrificial hard mask patterns 800a through an ashing process. For example, reaction gases such as N₂H₂ and O₂ are applied to the hard mask layer 800 to oxidize the portion of the hard mask layer 800 that is in proximity to the openings OP2, so as to form the sacrificial hard mask patterns 800a.

In some embodiments, each sacrificial hard mask pattern 800a is a tri-layered structure. For example, each sacrificial hard mask pattern 800a includes a first sub-layer 810a, a second sub-layer 820a, and a third sub-layer 830a. In some embodiments, the first sub-layer 810a, the second sub-layer 820a, and the third sub-layer 830a are stacked on the first spacer 322 in sequential order. In other words, the second sub-layer 820a is sandwiched between the first sub-layer 810a and the third sub-layer 830a. In some embodiments, a material of the first sub-layer 810a and a material of the third sub-layer 830a are the same. Meanwhile, a material of the second sub-layer 820a is different from the material of the first sub-layer 810a and the third sub-layer 830a. For example, the material of the first sub-layer 810a and the third sub-layer 830a includes silicon oxynitride or the like. On the other hand, the material of the second sub-layer 820a includes silicon oxide or the like. However, the disclosure is not limited thereto. In some alternative embodiments, the material of the first sub-layer 810a, the material of the second sub-layer 820a, and the material of the third sub-layer 830a are all different. As illustrated in FIG. 1G, each sacrificial hard mask pattern 800a is strip-like from the top view. In some embodiments, the strip-like sacrificial hard mask patterns 800a are parallel to one another and extend along the second direction D2. In some embodiments, the sacrificial hard mask patterns 800a are in physical contact with the insulating structure 900. In some embodiments, the sacrificial hard mask patterns 800a are located in the second region R2, and are not located in the first region R1.

In some embodiments, the hard mask layer 800b is a tri-layered structure. For example, the hard mask layer 800b includes a first sub-layer 810b, a second sub-layer 820b, and a third sub-layer 830b. The first sub-layer 810b, the second sub-layer 820b, and the third sub-layer 830b are respectively similar to the first sub-layer 810, the second sub-layer 820, and the third sub-layer 830, so the detailed descriptions thereof are omitted herein.

Referring to FIG. 1G to FIG. 1H, FIG. 2G to FIG. 2H, and FIG. 3G to FIG. 3H, the sacrificial hard mask patterns 800a and the gate stacks 700 exposed by the openings OP2 are removed to form a plurality of openings OP3. For example, the gate stacks 710 located in the second regions R2 are removed. In some embodiments, the sacrificial hard mask patterns 800a and the gate stacks 700 exposed by the openings OP2 (i.e. the gate stacks 710 located in the second regions R2) are removed by a same process during a same step. For example, the removal of the sacrificial hard mask patterns 800a and the removal of the gate stacks 710 located in the second regions R2 are in-situ processes. In some embodiments, the sacrificial hard mask patterns 800a and the gate stacks 710 located in the second regions R2 are removed through a wet etching process. In some embodiments, the etchant for this wet etching process includes H₂SO₄, H₂O₂, NH₄OH, H₂O, and/a combination thereof. For example, the sacrificial hard mask patterns 800a and the gate stacks 710 located in the second regions R2 may be removed by performing an SPM etching process, which utilizes H₂SO₄ and H₂O₂ as etchants. Alternately, the sacrificial hard mask patterns 800a and the gate stacks 710 located in the second regions R2 may be removed by using H₂SO₄ alone as an etchant, and followed by a SC1 (standard clean 1) process, which utilized NH₄OH, H₂O₂, and H₂O. As illustrated in FIG. 1H, the openings OP3 extend along the second direction D2.

In some embodiments, each of the semiconductor fins 102 has a first segment 102a and a second segment 102b connected to the first segment 102a. In some embodiments, the first segment 102a is located in the first region R1 while the second segment 102b is located in the second region R2. As illustrated in FIG. 1H, FIG. 2H, and FIG. 3H, the openings OP3 are formed in the second regions R2. In some embodiments, the openings OP3 expose the first spacers 322 located in the second regions R2, a portion of each second segment 102b of the semiconductor fin 102 located in the second regions R2, and the insulators 200 located in the second regions R2. On the other hand, the first spacers 322 located in the first regions R1 are still covered by the hard mask layer 800b. Meanwhile, the first segments 102a of the semiconductor fins 102 and the insulators 200 located in the first regions R1 are still covered by the CESL 500, the interlayer dielectric layer 600, and the gate structures 700. It should be noted that since the sacrificial hard mask patterns 800a are disposed on the first spacers 322, the sacrificial hard mask patterns 800a may serve as shielding layers for the first spacers 322. As such, during the formation of the openings OP3, the first spacers 322 in the second regions R2 are shielded by the sacrificial hard mask patterns 800a and are not being damaged by the etchant.

Referring to FIG. 1H to FIG. 1I, FIG. 2H to FIG. 2I, and FIG. 3H to FIG. 3I, a portion of the exposed first spacers 322 and the exposed portion of the semiconductor fins 102 are removed to form a plurality of openings OP4. For example, a portion of the first spacers 322 located in the second regions R2 and a portion of each second segment 102b are removed. In some embodiments, the portion of the first spacers 322 located in the second regions R2 and the portion of each second segment 102b are removed through a dry etching process. In some embodiments, the etchant for this dry etching process includes gases of Cl₂, BCl₃, HBr, N₂, O₂, CO₂, SiCl₄, H₂, NF₃, CF₄, C₄F₆, C₄F₈, CHF₃, C₂H₂, CH₃F, CH₄, Ar, He, and/or a combination thereof.

As illustrated in FIG. 1I, FIG. 2I, and FIG. 3I, the openings OP4 are formed in the second regions R2. In some embodiments, the openings OP4 expose the remaining first spacers 322 located in the second regions R2, the second spacers 324 located in the second regions R2, and the insulators 200 located in the second regions R2. Meanwhile, the first spacers 322 and the second spacers 324 located in the first regions R1 are still covered by the hard mask layer 800b. As illustrated in FIG. 1I, the first segments 102a of the semiconductor fins 102 are continuous. Meanwhile, the second segments 102b of the semiconductor fins 102 are fragmented by the openings OP4. For simplicity and clarity, the remaining first spacers 322 located in the second regions R2 are not shown in FIG. 1I.

As illustrated in FIG. 2I and FIG. 3I, a top portion of each opening OP4 has substantially straight sidewalls and a bottom portion of each opening OP4 has inclined sidewalls. In some embodiments, since a portion of each second segment 102b of the semiconductor fin 102 is removed, the process shown in FIG. 1I, FIG. 2I, and FIG. 3I may be referred to as a “fin-cut process.” In some embodiments, during the removal of the portion of each second segment 102b of the semiconductor fin 102, a portion of the semiconductor substrate 100 is further removed. For example, a depth DEP measured from a top surface of the semiconductor fin 120 to a bottom surface of the opening OP4 is larger than the height H₁₂₀ of the semiconductor fin 102. In some embodiments, the depth DEP may be referred to as a “fin-cut depth” and ranges from about 5 nm to about 300 nm. As illustrated in FIG. 2I and FIG. 3I, the openings OP4 extend into the semiconductor substrate 100. For example, the openings OP4 extend below the top surface T₁₀₀ of the semiconductor substrate 100. In some embodiments, a maximum width W_{OP4} of the openings OP4 ranges from about 5 nm to about 100 nm.

As mentioned above, during the process shown in FIG. 1H, FIG. 2H, and FIG. 3H, the openings OP3 are formed to a sufficient size (i.e. a large critical dimension (CD)) for fin-cut without damaging the first spacers 322 located in the second regions R2. In other words, the first spacers 322 still maintain a sufficient thickness. Therefore, during the formation of the openings OP4 (i.e. the fin-cut process), the first spacers 322 may serve as shielding layers for the second spacers 324, the CESL 500, and the interlayer dielectric layer 600. That is, during the fin-cut process, the first spacers 322 shields the second spacers 324, the CESL 500, and the interlayer dielectric layer 600 from being damaged laterally by the etchant. As such, the yield of the subsequently formed FinFET 10 may be enhanced and the performance of the subsequently formed FinFET 10 may be ensured.

Referring to FIG. 1J, FIG. 2J, and FIG. 3J, a plurality of isolation structures 1000 is formed in the openings OP4 to obtain a FinFET 10. In some embodiments, the isolation structures 1000 penetrate through the hard mask layer 800 located in the second regions R2, the composite spacers 320 located in the second regions R2, and the second segments 102b of the semiconductor fins 102 located in the second regions R2. In some embodiments, the isolation structures 1000 further extend into the semiconductor substrate 100. For example, the isolation structures 1000 extend below the top surface T₁₀₀ of the semiconductor substrate 100.

In some embodiments, the isolation structures 1000 include silicon oxide, silicon nitride or a suitable insulating material. In some embodiments, the isolation structures 1000 are deposited through CVD, PVD, ALD, or other suitable deposition process. In some embodiments, the isolation structures 1000 are made of a single material. However, the disclosure is not limited thereto. In some alternative embodiments, the isolation structures 1000 include a multi-layer structure.

As illustrated in FIG. 1J, the gate structures 700 are located in the first regions R1 while the isolation structures 1000 are located in the second regions R2. In some embodiments, each of the gate structures 700 and each of the isolation structures 100 extend along the second direction D2. That is, the gate structures 700 are parallel to the isolation structures 1000 from the top view. In some embodiments, the insulating structure 900 extends along the first direction D1. In other words, the insulating structure 900 is perpendicular to the gate structures 700 and the isolation structures 1000 from the top view. For example, the insulating structure 900 is sandwiched between the isolation structures 1000 and the gate structures 700. In some embodiments, the insulating structure 900 is in physical contact with the gate structures 700 and the isolation structures 1000.

As illustrated in FIG. 2J and FIG. 3J, each isolation structure 1000 has a first portion 1000a and a second portion 1000b stacked on the first portion 1000a. In some embodiments, sidewalls SW₁₀₀₀ₐ of the first portion 1000a are inclined. For example, a width of the first portion 1000a gradually decreases from top to bottom. As illustrated in FIG. 2J, the first portion 1000a exhibits a trapezoidal shape from the cross-sectional view. In some embodiments, sidewalls SW_{1000b} of the second portion 1000b are straight. For example, a width W₁₀₀₀b of the second portion 1000b is constant. As illustrated in FIG. 2J, the second portion 1000b exhibits a rectangular shape from the cross-sectional view. In some embodiments, a width W₁₀₀₀b of the second portion 1000b of the isolation structure 1000 is greater than a maximum width W₁₀₀₀ₐ of the first portion 1000a of the isolation structure 1000. In some embodiments, top surfaces T₁₀₀₀ₐ of the first portions 1000a of the isolation structures 1000 are coplanar with the top surfaces T₇₀₀ of the gate structures 700. In some embodiments, the second portions 1000b of the isolation structures 1000 cover top surfaces T₃₂₄ of the second spacers 324 located in the second regions R2. For example, bottom surfaces B_{1000b} of the second portions 1000b of the isolation structures 1000 cover the top surfaces T₃₂₄ of the second spacers 324 located in the second regions R2. In some embodiments, the bottom surfaces B_{1000b} of the second portions 1000b of the isolation structures 1000 are coplanar with a bottom surface B_{800b} of the hard mask layer 800b.

In some embodiments, each of the first spacers 322 located in the second regions R2 is sandwiched between the first portion 1000a of the corresponding isolation structure 1000 and the corresponding second spacer 324. As illustrated in FIG. 2J, each of the first spacers 322 located in the second regions R2 exhibits a triangular shape from the cross-sectional view while each of the second spacers 324 located in the second regions R2 exhibits a rectangular shape from the cross-sectional view. In some embodiments, each first spacers 322 located in the second regions R2 takes a form of right triangle from the cross-sectional view. As illustrated in FIG. 1J, the sidewalls SW_{1000b} of the second portion 1000b of each of the isolation structures 1000 are aligned with sidewalls SW₇₀₀ of the corresponding gate structure 700 from the top view.

As illustrated in FIG. 1J, FIG. 2J and FIG. 3J, the gate structures 700 are disposed across the first segments 102a of the semiconductor fins 102 in the first regions R1. Meanwhile, the isolation structures 1000 are sandwiched between fragments of the second segments 102b of the semiconductor fins 102 in the second regions R2. That is, the isolation structures 1000 cut each second segment 102b of the semiconductor fin 102 into fragments. In other words, the isolation structures 1000 interrupt a continuity of each second segment 102b of the semiconductor fin 102. In some embodiments, the process illustrated in FIG. 1I to FIG. 1J, FIG. 2I to FIG. 2J, and FIG. 3I to FIG. 3J is referred to as a “cut poly on OD edge (CPODE) process” and each of the isolation structure 1000 is referred to as a “CPODE layer.”

In some embodiments, after the FinFET 10 is formed, conductive contact structures may be further formed to penetrate through the hard mask layer 800b, so as to electrically connect the gate electrode 714 with other elements.

In accordance with some embodiments of the disclosure, a FinFET includes a semiconductor substrate, a semiconductor fin, a gate structure, and an isolation structure. The semiconductor fin protrudes from the semiconductor substrate. The gate structure is disposed across a first segment of the semiconductor fin. The isolation structure interrupts a continuity of a second segment of the semiconductor fin. The isolation structure has a first portion and a second portion stacked on the first portion. Sidewalls of the first portion are inclined and sidewalls of the second portion are straight. A top surface of the first portion is coplanar with a top surface of the gate structure.

In accordance with some alternative embodiments of the disclosure, a FinFET having a first region and a second region adjacent to the first region includes a semiconductor substrate, semiconductor fins, gate structures, and isolation structures. The semiconductor fins protrude from the semiconductor substrate. The semiconductor fins in the first region are continuous and the semiconductor fins in the second region are fragmented. The gate structures are located in the first region and are disposed across the semiconductor fins. The isolation structures are located in the second region and are sandwiched between fragments of the semiconductor fins in the second region. Each of the isolation structures has a first portion and a second portion stacked on the first portion. Each of the first portions exhibits a trapezoidal shape form a cross-sectional view. Each of the second portions exhibits a rectangular shape from the cross-sectional view. Top surfaces of the first portions are coplanar with top surfaces of the gate structures.

In accordance with some embodiments of the disclosure, a manufacturing method of a FinFET having a first region and a second region adjacent to the first region includes at least the following steps. A semiconductor substrate having semiconductor fins thereon is provided. Gate structures are formed across the semiconductor fins. Each of the gate structures includes a gate stack, a first spacer, and a second spacer, and the first spacer is sandwiched between the gate stack and the second spacer. A hard mask layer is deposited on the gate structures. First openings are formed in the second region to expose the gate stacks. Portions of the hard mask layer that are in proximity to the first openings are transformed into sacrificial hard mask patterns. The sacrificial hard mask patterns and the gate stacks exposed by the first openings are removed to form second openings exposing the first spacers and a portion of the semiconductor fins. A portion of the exposed first spacer and the exposed portion of the semiconductor fins are removed to form third openings. Isolation structures are formed in the third openings.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A fin field effect transistor (FinFET), comprising:
a semiconductor substrate;
a semiconductor fin, protruding from the semiconductor substrate;
a gate structure disposed across a first segment of the semiconductor fin; and
an isolation structure interrupting a continuity of a second segment of the semiconductor fin, wherein the isolation structure has a first portion and a second portion stacked on the first portion, sidewalls of the first portion are inclined, sidewalls of the second portion are straight, and a top surface of the first portion is coplanar with a top surface of the gate structure.

2. The FinFET of claim 1, wherein a width of the second portion of the isolation structure is greater than a maximum width of the first portion of the isolation structure.

3. The FinFET of claim 1, further comprising a first spacer and a second spacer, the first spacer is sandwiched between the first portion of the isolation structure and the second spacer.

4. The FinFET of claim 3, wherein the first spacer exhibits a triangular shape from a cross-sectional view, and the second spacer exhibits a rectangular shape from the cross-sectional view.

5. The FinFET of claim 4, wherein the second portion of the isolation structure covers a top surface of the second spacer.

6. The FinFET of claim 1, wherein the isolation structure extends below a top surface of the semiconductor substrate.

7. The FinFET of claim 1, wherein the isolation structure is parallel to the gate structure from a top view.

8. A fin field effect transistor (FinFET) having a first region and a second region adjacent to the first region, comprising:
a semiconductor substrate;
semiconductor fins protruding from the semiconductor substrate, wherein the semiconductor fins in the first region are continuous and the semiconductor fins in the second region are fragmented;
gate structures located in the first region, wherein the gate structures are disposed across the semiconductor fins; and
isolation structures located in the second region, wherein the isolation structures are sandwiched between fragments of the semiconductor fins in the second region, each of the isolation structures has a first portion and a second portion stacked on the first portion, each of the first portions exhibits a trapezoidal shape from a cross-sectional view, each of the second portions exhibits a rectangular shape from the cross-sectional view, and top surfaces of the first portions are coplanar with top surfaces of the gate structures.

9. The FinFET of claim 8, further comprising a hard mask layer disposed on the gate structures, and a bottom surface of the second portion is coplanar with a bottom surface of the hard mask layer.

10. The FinFET of claim 8, wherein sidewalls of the second portion of each of the isolation structures are aligned with sidewalls of the corresponding gate structure from a top view.

11. The FinFET of claim 8, further comprising first spacers and second spacers, each of the first spacers is sandwiched between the first portion of the corresponding isolation structure and the corresponding second spacer.

12. The FinFET of claim 11, wherein each of the first spacers exhibits a triangular shape from the cross-sectional view, and each of the second spacer exhibits a rectangular shape from the cross-sectional view.

13. The FinFET of claim 8, further comprising an insulating structure sandwiched between the isolation structures and the gate structures.

14. The FinFET of claim 13, wherein the insulating structure extends along a first direction, the gate structures and the isolation structures extend along a second direction, and the first direction is perpendicular to the second direction.

15. A manufacturing method of a fin field effect transistor (FinFET) having a first region and a second region adjacent to the first region, comprising:
providing a semiconductor substrate having semiconductor fins thereon;
forming gate structures across the semiconductor fins, wherein each of the gate structures comprises a gate stack, a first spacer, and a second spacer, and the first spacer is sandwiched between the gate stack and the second spacer;
depositing a hard mask layer on the gate structures;
forming first openings in the second region to expose the gate stacks;
transforming portions of the hard mask layer that are in proximity to the first openings into sacrificial hard mask patterns;
removing the sacrificial hard mask patterns and the gate stacks exposed by the first openings to form second openings exposing the first spacers and a portion of the semiconductor fins;
removing a portion of the exposed first spacer and the exposed portion of the semiconductor fins to form third openings; and
forming isolation structures in the third openings.

16. The method of claim 15, further comprising:
forming an insulating structure penetrating through the hard mask layer and the gate stacks before the first openings are formed, wherein the insulating structure extends into the semiconductor substrate.

17. The method of claim 15, wherein the portions of the hard mask layer is transformed into the sacrificial hard mask patterns by oxidizing the portions of the hard mask layer that are in proximity to the first openings.

18. The method of claim 15, wherein the sacrificial hard mask patterns and the gate stacks exposed by the first openings are removed through a wet etching process, and the portion of the exposed first spacers and the exposed portion of the semiconductor fins are removed through a dry etching process.

19. The method of claim 15, wherein the sacrificial hard mask patterns and the gate stacks exposed by the first openings are removed by a same process during a same step.

20. The method of claim 15, further comprising:
forming dummy gate structures across the semiconductor fins, wherein each of the dummy gate structures comprises a dummy gate stack, the first spacer, and the second spacer, and the first spacer is sandwiched between the dummy gate stack and the second spacer;
removing the dummy gate stacks to form fourth openings; and
forming the gate stacks in the fourth openings, so as to form the gate structures.
